(19) United States
(12) Patent Application Publication
(10) Pub. No.: US 2005/0174841 A1
(43) Pub. Date: Aug. 11, 2005

(54) Electronic memory with tri-level cell pair

(75) Inventor: Iu-Meng Tom Ho, Milpitas, CA (US)

Correspondence Address: PATTON BOGGS, 1660 LINCOLN ST, SUITE 2050, DENVER, CO, 80264, US

(73) Assignee: Iota Technology, Inc., San Jose, CA (US)

(21) Appl. No.: 11/049,236

(22) Filed: Feb. 2, 2005

Related U.S. Application Data
(60) Provisional application No. 60/542,094, filed on Feb. 5, 2004.

(51) Int. Cl. G11C 11/34

(52) U.S. Cl. 365/185.03

(57) ABSTRACT

An electronic memory comprising a memory cell pair with each memory cell capable of existing in three or more electronic memory states so that the pair is capable of existing in nine electronic states. The memory cell is capable of storing three data bits plus an extra state that can be used for data integrity. The memory can be a flash memory, an ROM, a dynamic memory, an OUM, an MRAM, an NAND memory or an NOR memory.

### RELATED APPLICATIONS

This patent application claims the benefit of U.S. Provisional Patent Application No. 60/542,094 filed Feb. 5, 2004, which provisional patent application is hereby incorporated by reference to the same extent as though fully disclosed herein.

### BACKGROUND OF THE INVENTION

1. Field of the Invention

The invention in general relates to electronic memories, and in particular such memories capable of storing multiple data bits (M) in a single memory cell or multiple memory cells (N) where (M) is greater than (N).

2. Statement of the Problem

Electronic memories comprising arrays of memory cells arranged in rows and columns are well known. Most such memories are capable of storing a single bit of data in each memory cell. However, as the need for denser memories has grown and the ability to detect smaller voltages, currents, and/or charges has developed, memories that store multiple bits of data per cell have become commercially available. These include two-bit-per-cell Read Only Memory (ROM), two- or multiple-bits-per-cell dynamic random access memory (DRAM), multi-level flash memories, two-bit-per-cell MLC StrataFlash™ developed by Intel, two-bit-per-cell mirror bit flash developed by AMD, Ovonic Unified Memory (OUM), Magnetoresistive Random Access Memory (MRAM), EEPROM multi-bit cells, EPROM multi-bit cells, CCD (Charge Coupled Device) memory cells, and many others. There are hundreds of patents describing the design details for such memories, including U.S. Pat. No. 4,287,570 describing a multiple-bit ROM NOR memory, U.S. Pat. No. 4,388,702 describing a multiple-bit ROM memory with virtual ground, U.S. Pat. No. 4,586,163 describing a multiple-bit ROM NAND memory, U.S. Pat. No. 4,653,023 describing a plural-bit-per-cell ROM NOR memory, U.S. Pat. No. 4,771,404 describing a two-bits-per-cell DRAM, U.S. Pat. No. 5,351,210 describing a serially accessible multi-bit-per-cell DRAM, U.S. Pat. No. 4,661,929 describing a multi-bit-per-cell DRAM, U.S. Pat. No. 5,283,761 describing a multi-level DRAM cell, U.S. Pat. No. 4,964,079 describing a multi-bit-per-cell flash memory, U.S. Pat. No. 5,043,940 describing a multi-state flash memory cell, U.S. Pat. No. 5,218,569 describing an N-bits-per cell flash memory, U.S. Pat. No. 5,790,456 describing a multiple-bits-per-cell flash EEPROM, and U.S. Pat. No. 5,515,324 describing a NAND flash memory.

For all of the above memory cells, it is necessary to distinguish four or more voltage levels over the same voltage range that two voltage levels are distinguished in one-bit-per-cell memories. For example, if the conventional cell has a zero volts as logic “0” state and five volts as the logic “1” state, a two-bit cell using the same cell structure must be able to distinguish a zero volt state, a 1.67 volt state, a 3.33 volt state and a five volt state. However, at the same time that there is a demand for denser memories, there is also a demand for memories using less power. Further, the drive for higher densities also requires smaller and smaller circuit footprints, including thinner insulation layers. Thinner insulation layers require lower voltages to prevent unsuitably high leakage currents. If the system voltage is scaled down to achieve less power and suitably small leakage currents in small footprint devices, the voltage differences that must be distinguished become correspondingly small, and it is difficult, if not impossible, to develop reliable read/write circuitries, especially for the Very Deep Submicron Technologies (VDS) with the scaling of system supply voltage down to 1.0 volt or lower. Thus, when reliability, accessing time performance, and/or low power consumption are important, commercial electronic devices uniformly utilize conventional one-bit per cell architectures.

From the above, it is evident that there is a need for an electronic memory architecture that is denser than a one-bit-per-cell architecture, which can be scaled to small footprints and low voltages, and at the same time is highly reliable.

### SUMMARY OF THE INVENTION

The invention provides a solution to the above problem by providing a memory architecture that utilizes three voltage levels per cell, which we shall refer to herein as the Tri-Level Cell (TLC). Since it is inherently easier to distinguish three voltage levels in a cell, as compared to four or more levels per cell, such a memory can be more easily scaled down to small footprints and low power.

The memory architecture according to the invention utilizes multiple memory cells to obtain three or more bits of data. For example, in the preferred embodiment, two tri-level memory cells (TLCs) are used to obtain three bits of data in a TLC cell pair, thus increasing the memory storage capacity by 50% with roughly the same die area. It is preferred that each of the multiple-level cells has only one extra level from a conventional single bit memory cell, i.e., three levels: Since one TLC cell only has three logic states, two TLC cells are required to get nine logic states, which is enough to represent three bits of data storage with one extra state. We will call this a Tri-level Cell Pair strategy. The two single-bit TLC cells can be combined in one cell or can be placed in different locations as required by layout and circuit design considerations. The one extra state is preferably used as a violation state, un-programmed, privileged state, etc., which is not available from the existing multi-level cell (MLC) designs, nor the Single-level Cell (SLC designs). As known in the art, such an extra state can be used to increase reliability of the overall cell architecture.

The invention provides an electronic memory comprising: a memory cell pair comprising a first memory cell and a second memory cell, each said memory cell comprising an electronic storage element, e.g., a single bit line cell or elements or complementary bit line cells, capable of existing in three or more electronic memory states; a write circuit for writing three or more data bits to said memory cell pair, wherein at least one of said data bits is used to determine an electronic memory state of said first cell and an electronic memory state of said second cell; and a read circuit for reading three or more data bits from said memory cell pair, wherein at least one data bit is determined by an electronic memory state of said first cell and an electronic memory state of said second cell. Preferably, said memory cell pair includes an extra state that is not used in representing said three or more data bits. Preferably, said first and second memory cells are capable of existing in an odd number of states. Preferably, said first and second memory cells are capable of existing in three electronic memory states for a total of nine possible memory state combinations and there are three of said data bits. Preferably, one of said nine possible memory state combinations is not used in directly recording said three data bits. Preferably, said memory further includes a tri-level sense amplifier for sensing three electronic levels and for outputting two logic signals. Preferably, said memory includes two of said tri-level sense amplifiers and a decoder for decoding the four logic signals output by said sense amplifiers into three data bits. The single-bitline-cell or complementary-bitline-cell memory can be a flash memory, a read only memory (ROM), a ferroelectric memory (FeRAM) or (FRAM), a dynamic memory such as dynamic random access memory (DRAM) or a dynamic register, an ovonic unified memory (OUM), or a magnetoresistive random access memory (MRAM). In the case of a dynamic memory, the memory cells preferably include an MOS capacitor, and more preferably, an NMOS capacitor. The memory can be ferroelectric memory, which may be a non-volatile memory, a destructive read out memory, or a non-destructive readout memory. The memory may also be either an NAND memory or an NOR memory.

The invention also provides a method of reading an electronic memory, said method comprising: reading three electronic levels from each of 2N memory cells, where N is an integer; and decoding said electronic levels into 2N+N data bits. Preferably, said reading comprising reading three electronic levels from each of two memory cells, and said decoding comprises decoding said electronic levels into three data bits. For a complementary-bit-line-cell when the true-and-complement storage elements, which can be capacitive or resistive, can store “0” or “1” value independently, the three levels can also be represented by the normal, e.g., “01”=High, “10”=Low, and the third level can be “11 or 00”=Middle.

In another aspect, the invention provides a method of writing to an electronic memory, said method comprising: receiving 2N+N bits of data, where N is an integer; and writing said bits of data into three electronic levels in each of 2N memory cells. Preferably, said receiving comprises receiving three data bits, and said writing comprises writing three electronic levels into each of two memory cells.

The Tri-Level TLC Cell Pair strategy gives a 50% increase in memory storage capacity with a much less challenging circuit development effort as compared to Multi-level Cell (MLC) designs, with very minor additional die area. Any of the non-volatile technologies like EEPROM, EPROM, FeRAM, Silicon-On-Fe-Capacitor FeRAM, OUM memory, and various types of flash memories, which include stacked-gate cell, two-transistor cell (MirrorBit), split-gate cell, etc., can be easily modified to provide the 50% increase in storage capacity. All synchronous or asynchronous DRAMs, Silicon-On-Capacitor DRAMs, PSRAMs, and 1TSRAMs can also be converted to this Tri-Level TLC Cell Pair strategy to gain a 50% storage capacity. Numerous other features, objects, and advantages of the invention will become apparent from the following description when read in conjunction with the accompanying drawings.

### BRIEF DESCRIPTION OF THE DRAWING

FIG. 1 is a generalized circuit diagram illustrating the paired tri-level-cell architecture according to the invention;

FIG. 2 is a block circuit diagram illustrating the architecture of a paired tri-level-cell architecture during the read operation according to the invention;

FIG. 3 is a block circuit diagram illustrating the paired tri-level-cell architecture during the write operation according to the invention;

FIG. 4 is a circuit diagram illustrating the paired tri-level-cell architecture of a NAND flash memory according to the invention;

FIG. 5 is a circuit diagram illustrating a portion of an alternative architecture of a NAND flash memory according to the invention in which the BLA lines are replaced by a CSL line;

FIG. 6 is a circuit diagram illustrating a three-bit-per-cell TLC virtual ground NOR flash memory core architecture according to the invention;

FIG. 7 is a circuit diagram illustrating a six-bit-per-cell TLC virtual ground NOR flash memory core architecture according to the invention;

FIG. 8 is a circuit diagram illustrating an alternative three-bit-per-cell TLC NOR flash memory core architecture according to the invention;

FIG. 9 is a circuit diagram illustrating a TLC Ovonic Unified Memory (OUM) according to the invention;

FIG. 10 is a circuit diagram illustrating a TLC Magnetoresistive RAM (MRAM) according to the invention;

FIG. 11 is a circuit diagram illustrating a TLC DRAM cell pair according to the invention;

FIG. 12 is a circuit diagram illustrating a TLC dynamic register cell pair according to the invention;

FIG. 13 is a circuit diagram illustrating a TLC NOR ROM cell pair according to the invention;

FIG. 14 is a circuit diagram illustrating a TLC NAND ROM cell pair according to the invention;

FIG. 15 shows a ferroelectric hysteresis curve illustrating how a ferroelectric memory cell can exist in three different states;

FIG. 16 is a circuit diagram illustrating a TLC FERAM cell pair according to the invention; and

FIG. 17 is a circuit diagram illustrating a TLC DRAM pair with MOS capacitors.

### DETAILED DESCRIPTION OF THE PREFERRED EMBODIMENT

1. Overview

The invention relates to electronic memories. These memories include memory arrays comprising rows and columns of memory cells electrically connected with signal lines, such as word lines and bit lines, plus associated circuitry for writing and reading to the memory.

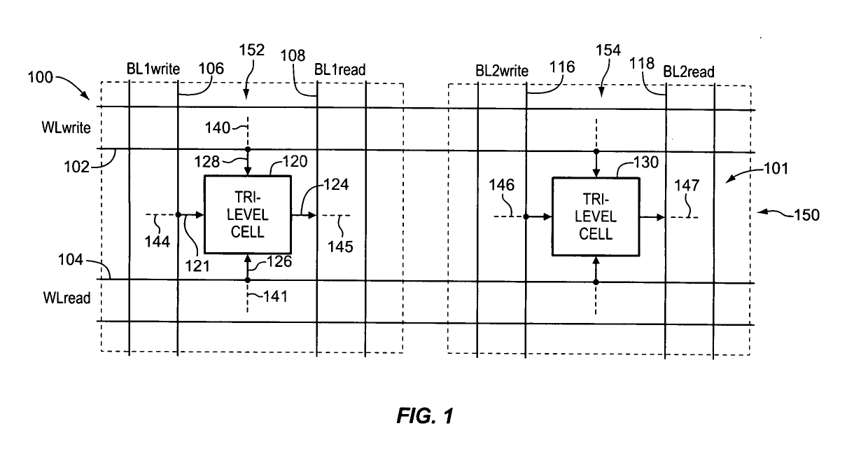

FIG. 1 shows a generalized circuit diagram illustrating the paired tri-level-cell (TLCP) architecture according to the invention. Memory array portion 100 includes a cell pair 101 comprising a first tri-level cell 120 and a second tri-level cell 130. Tri-level means that the cell can exist in three electronic states. For a single bit line cell, the cell can have a single storage element, and the bitlines, e.g., 106, is a single bit line. For a complementary-dual-bit-lines-cell, the cell can have two storage elements, and the bit-lines, e.g. 106, represents two bit-lines which are normally used as true-and-complement data. It should be noted that the word “state” is used in two different senses in this disclosure. In one sense, it refers to the electronic state, such as charge state or resistance state, of a single one of the cells, such as 120, of a cell pair 101. For a single bit line cell, this state refers to the levels of charge or resistance state in the storage element of the corresponding cell. For a complementary-dual-bit-lines-cell, this state refers to the charge and resistance states as in a single bit-line cell, and the combinations of the bit and bit-bar states, which can be, e.g., “0, 1” representing one level, “1, 0” representing the second level, “1, 1” or “0, 0” representing the additional third level for a Tri-level memory cell. In another sense, it refers to the state of a cell pair 101. A state of a cell pair 101 consists of one of the cell pair being in a specific one of its three possible states, and the other of the cell pair being in a specific one of its three possible states. Thus, there are nine different states available to the cell pair 101.

Cells 120 and 130 are addressed by word write line 102 carrying a write signal WLwrite and word read line 104 carrying a word read signal WLread. Cell 120 is also addressed by write bit line 106 carrying signal BL1write and read bit line 108 carrying signal BL1read, while cell 130 is also addressed by write bit line 116 carrying signal BL2 and read bit line 118 carrying signal BL2. Each cell, such as 120, has a write port 121 connected to the write bit line 106 and a read port 124 connected to the read bit line and is connected to the write word line 102 and read word line 104 via address lines 128 and 126, respectively. Generally, there are additional rows of cells above and below row 150 as indicated by dotted lines 140 and 142 and additional columns of cells to the left and right of columns 152 and 154 as indicted by dotted lines 141 and 147, respectively. There also may be additional columns of cells between columns 152 and 154 as indicated by dotted lines 145 and 146; that is, cell pair 101 is not necessarily comprised of neighboring cells.

As will be shown in the examples below, each tri-level cell 120 and 130 preferably comprises a single tri-level storage element for a single bit line architecture, and two storage elements for a complementary-dual-bit-lines architecture. By “a single tri-level storage element” is meant a single capacitor, a single transistor, or a single resistor, a single magnetoresistive element, or a single other element that is conventionally used as a storage element in an electronic memory. It is noted that some memory cells, such as dual floating gate NAND flash cell, actually contain two storage elements, since the floating gate has an insulating portion which divides the gate in two. This is not considered to be a single storage element, since there are two separate storage gates in the dual gate structure. In general, the most common tri-level storage element can be of two types: resistive, which depends on variation of drive strengths or threshold voltage variation to provide the three levels; or capacitive, which depends on the amount of charge stored or variation of capacitance to provide the three levels. In general, each port, read or write, can have its own corresponding control lines and bit line, or control lines can be shared or merged depending on timing and applications; bit lines can also be shared, merged, or joined serially depending on timing and applications, or read and write ports can also be shared or merged together depending on the applications. Some examples include: a NOR flash cell is a resistive type single port READ/WRITE with merged word line and bit line; a NAND flash cell is a resistive type single port READ/WRITE with merged word line, and serially joined bit lines; a NOR virtual ground flash cell is a resistive type single port READ/WRITE with merged word line, and shared bit lines; a NOR ROM cell is a resistive type single port READ; a NAND ROM cell is a resistive type single port READ with serially joined bit lines; a NOR virtual ground ROM cell is a Resistive type single port READ with shared bit lines; a DRAM cell is a capacitive type single port READ/WRITE with merged word line and bit line; a dynamic 1R1W register cell is a capacitive type one read port and one write port; a dynamic 1R2W register cell is a capacitive type one read port and two write ports; a dynamic 2R2W register cell is a capacitive type two read ports, and two write ports; an OUM cell is a resistive type single-port READ/WRITE with merged word line and bit line; an MRAM cell is a resistive type single port READ/WRITE with merged word line and bit line; a 1T1C FeRAM cell is a capacitive type single port READ/WRITE with one bit line, and two word lines with one of the word lines used as a plate line. If any of the above memories is implemented with complementary-dual-bit-line cells, the three levels of the Tri-Level Cell can be represented in the True-&-Complement cell as “0, 1” as the first level, “1, 0” as the second level, “1, 1” or “0, 0” as the third level.

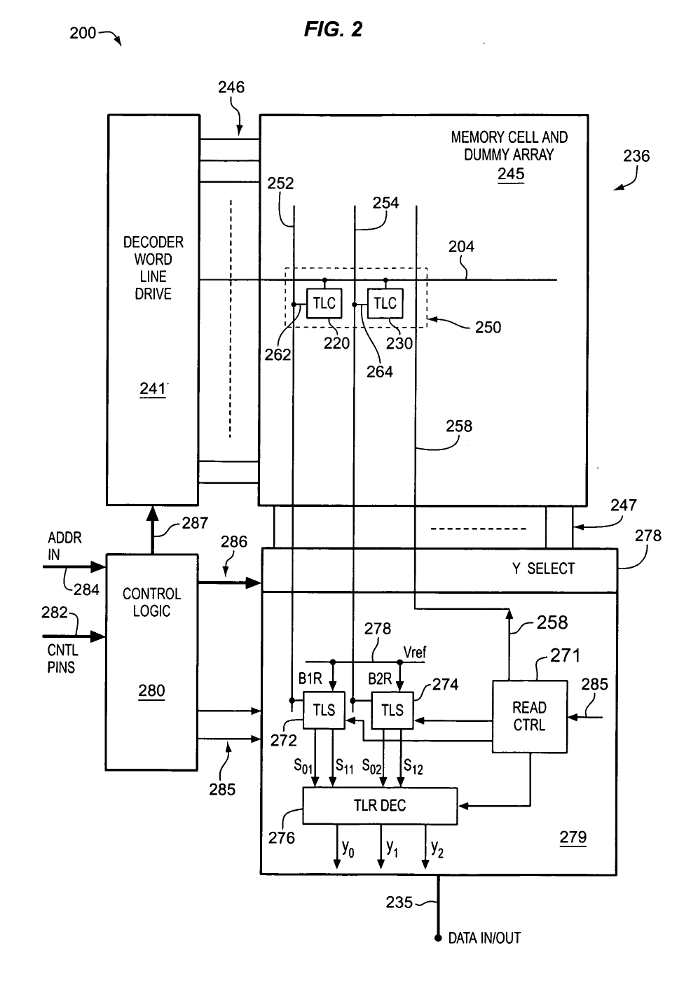

FIG. 2 shows an exemplary TLCP memory 200 according to the invention illustrating the read circuitry 436, illustrating how a TLC Pair 250 is used to obtain three bits of digital data, Y0, Y1, and Y2. Each of the TLC cells 220 and 230 has its own corresponding tri-level sense amplifier (TLS) 272 and 274, respectively, connected to its read port, 262 and 264, respectively, via its corresponding bit line 252 and 254, respectively.

MEMORY 200 includes decoder and word line drive 441, memory cell array 245, column (y) selector circuit 278, input/output circuitry 279, and control logic 280. Memory cell array 245 includes tri-level cell pair 250, read word line 204, read bit lines 252, optionally decoded read drive line 258, as well as other cell pairs and word and drive lines as discussed above in connection with FIG. 1. The cell pairs and drive lines are not shown in order to make the connections between the exemplary cells and lines clearer. Array 245 also includes dummy cells in architectures that include dummy cells. Cell pair 250 includes first memory cell 220 and second memory cell 230, which are connected to read word line 204. Cell 220 is also connected to read bit line 252, while cell 230 is connected to read bit line 253.

Read Control logic 280 receives control signals from control pins 282 and address signals on address lines 284 and provides row address signals to decoder 241 on row address bus 287, column address signals to column selector circuit 278 on column address bus 286, and provides input/output control signals to input/output circuit 279 on lines 285. Row decoder 441 decodes the row address and applies word line signals on word lines 246, including the read word line 204 associated with cells 220 and 230. Input/output circuitry 279 includes tri-level sense amplifiers 272 and 274, read control circuitry 271, and tri-level decoder 276. The inputs to tri-level sense amplifiers 272 and 274 include a read control signal, a voltage reference signal Vref from reference voltage source 278, and the bit line signal B1 and B2, respectively, from the corresponding read bit lines 252 and 254. Each tri-level sense amplifier outputs two signals, S01 and S02, from tri-level sense amplifier 272, and S02 and S12 from sense amplifier 274, which signals are input into tri-level decoder 276. An example of how each sense amplifier maps the three logic levels to the two output signals S0 and S1 is shown in Table 1:

TABLE 1

| S0 | S1 | |
|---|---|---|
| 0 | X | Logic Level on the Bit line is LOW |
| 1 | 0 | Logic Level on the Bit line is Medium |
| 1 | 1 | Logic Level on the Bit line is High |

In Table 1, the zeros and ones represent corresponding logic states and the X represents a “don't care” state. As another example, each of the tri-level sense amps 272 and 274 can also have three outputs representing directly the low, medium, and high levels, i.e., SL, SM, and SH.

The read control circuit 271 also inputs a signal to tri-level sense amplifier 276. The output from tri-level read decoder 276 is a three-bit data signal Y0, Y1, Y2 output on data out bus 235. The ideal location for placing Error Detection And Correction Circuits (ECC or EDAC) is at the input section of the tri-level read decoder 276. To simplify the ECC algorithm, the physical failure mechanism can be exploited. For a capacitive charge storage element, the failure mode would mostly be total charge lost. If the capacitor can retain any charge, it is a good capacitor. The Medium and High states can be viewed as one state. The ECC would only need to worry about with or without charge states. For resistive type memory like Flash and OUM, the failure mode would mostly be an extra fast programmed cell. It means that the cell would be high resistance or high threshold whenever it is programmed. The Low programmed state and the Medium programmed state can be viewed as one state. The ECC would only need to worry about conductive or not-conductive states; or in another words Low threshold states or High threshold states. In the case of ferroelectric memory, one of the failure modes would be that the ferroelectric capacitor has lost all the polarization charge. The ECC would only need to worry about with or without polarization charge states.

Two different samples of decoding maps from the S01, S11, S02, and S12 signals to the Y0, Y1, and Y2 signals are shown in Table 2 and Table 3.

TABLE 2

| S01 | S11 | S02 | S12 | Y0 | Y1 | Y2 |
|---|---|---|---|---|---|---|
| 0 | X | 0 | X | 0 | 0 | 0 |
| 0 | X | 1 | 0 | 0 | 0 | 1 |
| 0 | X | 1 | 1 | 0 | 1 | 0 |
| 1 | 0 | 0 | X | 0 | 1 | 1 |
| 1 | 0 | 1 | 0 | 1 | 0 | 0 |
| 1 | 0 | 1 | 1 | 1 | 0 | 1 |
| 1 | 1 | 0 | X | 1 | 1 | 0 |
| 1 | 1 | 1 | X | 1 | 1 | 1 |

| | | | | |
|---|---|---|---|---|
| 1 | 1 | 1 | 1 | (Extra State) |

TABLE 3

| S01 | S11 | S02 | S12 | Y0 | Y1 | Y2 |
|---|---|---|---|---|---|---|
| 0 | X | 0 | X | (Extra State) | | |
| 0 | X | 1 | 0 | 0 | 0 | 0 |
| 0 | X | 1 | 1 | 0 | 0 | 1 |
| 1 | 0 | 0 | X | 0 | 1 | 0 |
| 1 | 0 | 1 | 0 | 0 | 1 | 1 |
| 1 | 0 | 1 | 1 | 1 | 0 | 0 |
| 1 | 1 | 0 | X | 1 | 0 | 1 |
| 1 | 1 | 1 | 0 | 1 | 1 | 0 |
| 1 | 1 | 1 | 1 | 1 | 1 | 1 |

The decoding maps are selected depending on circuit design considerations. The Extra State can also be used as unprogrammed, unknown, violation, privileged, etc. If data output 235 is a bus and Y0, Y1, Y2 are output in parallel, they represent three separate data outputs. If data output 235 is a single pin and Y0, Y1, Y2 are sent in series through one pin, they can be considered as three different values for one data output.

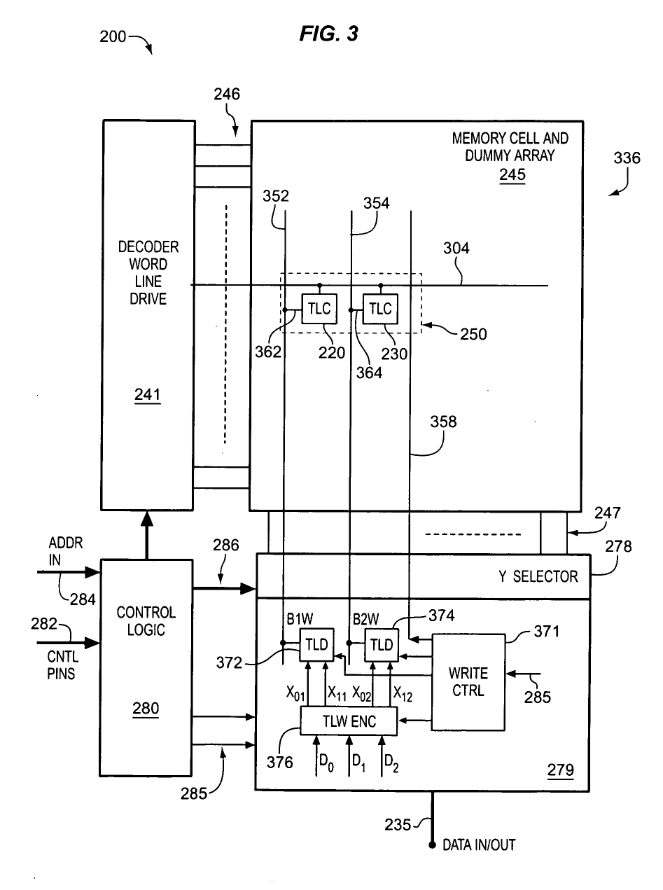

FIG. 3 shows an exemplary TLCP memory 200 according to the invention illustrating the write circuitry 336 for writing data to the TLC pair 250. This memory 200 is the same as the memory of FIG. 3 except the write portions are shown. Identical elements are identified with the same numerals as used in FIG. 2. In addition to these elements, memory 200 includes write bit lines 352 and 354 and write ports 362 and 364 associated with tri-level cells 220 and 230, respectively, write word line 304, tri-level drivers 372 and 374, tri-level encoder, write control circuit 371 which receives inputs from lines 285, and optional Y-decoded write drive line 358. FIG. 3 illustrates the circuitry for encoding three data bits D0, D1, and D2 and are encoded into tri-level LOW, MEDIUM, and HIGH states and written into cells 220 and 230.

The data inputs D0, D1, D2 can be first encoded by encoder 376 into X01, X11 for TLC cell 220, and X02, X12 for TLC cell 230 and then by drivers 372 and 374, respectively, into LOW, MEDIUM and HIGH signals for writing to the respective cells. Tables 4, 5, and 6 illustrate how this can be done. The encoder 376 first encodes the D0, D1, and D2 signals into two signals X0 and X1 for each TLC cell 220 (TLC1) and 230 (TLC2) according to Table 4:

TABLE 4

| D0 | D1 | D2 | X01 | X11 | X02 | X12 |
|---|---|---|---|---|---|---|
| (Extra State) | | | 0 | X | 0 | X |
| 0 | 0 | 0 | 0 | X | 0 | X |
| 0 | 0 | 1 | 0 | X | 1 | 0 |
| 0 | 1 | 0 | 0 | X | 1 | 1 |
| 0 | 1 | 1 | 1 | 0 | 0 | X |
| 1 | 0 | 0 | 1 | 0 | 1 | 0 |
| 1 | 0 | 1 | 1 | 0 | 1 | 1 |
| 1 | 1 | 0 | 1 | 1 | 0 | X |
| 1 | 1 | 1 | 1 | 1 | 1 | X |

where X indicates a “don't care” state as before. Within the tri-level drivers 372 and 374, respectively, the two input signals X0 and X1 are interpreted as shown in Table 5:

TABLE 5

| X0 | X1 | |
|---|---|---|
| 0 | X | Write LOW command |
| 1 | 0 | Write Medium command |
| 1 | 1 | Write High command |

Thus, the three bits D0, D1, and D2 each result in the following states being written into the cells 220 (TLC1) and 230 (TLC2) as shown in Table 6:

TABLE 6

| D0 | D1 | D2 | TLC1 | TLC2 |
|---|---|---|---|---|
| (Extra State) | | | LOW | LOW |
| 0 | 0 | 0 | LOW | MEDIUM |
| 0 | 0 | 1 | LOW | HIGH |
| 0 | 1 | 0 | MEDIUM | LOW |
| 0 | 1 | 1 | MEDIUM | MEDIUM |
| 1 | 0 | 0 | MEDIUM | HIGH |
| 1 | 0 | 1 | HIGH | LOW |
| 1 | 1 | 0 | HIGH | MEDIUM |
| 1 | 1 | 1 | HIGH | HIGH |

The outputs of the Tri-Level Write Encoder TLWENC are the TLWENC can also write out the LOW, MEDIUM, or HIGH commands directly to write into the Tri-Level storage element for each corresponding TLC cell. Different encoding maps can be selected depending on circuit design considerations. The extra state can be used as an unprogrammed, unknown, violation, privileged state, etc., depending on circuit applications. In the case of a flash memory, the extra state can be one in which both cells are erased by no data being written into the cell. In the case of a DRAM, the cells during power startup will most likely have no charge in them. It can be considered a violation if the cells were not written but are being read.

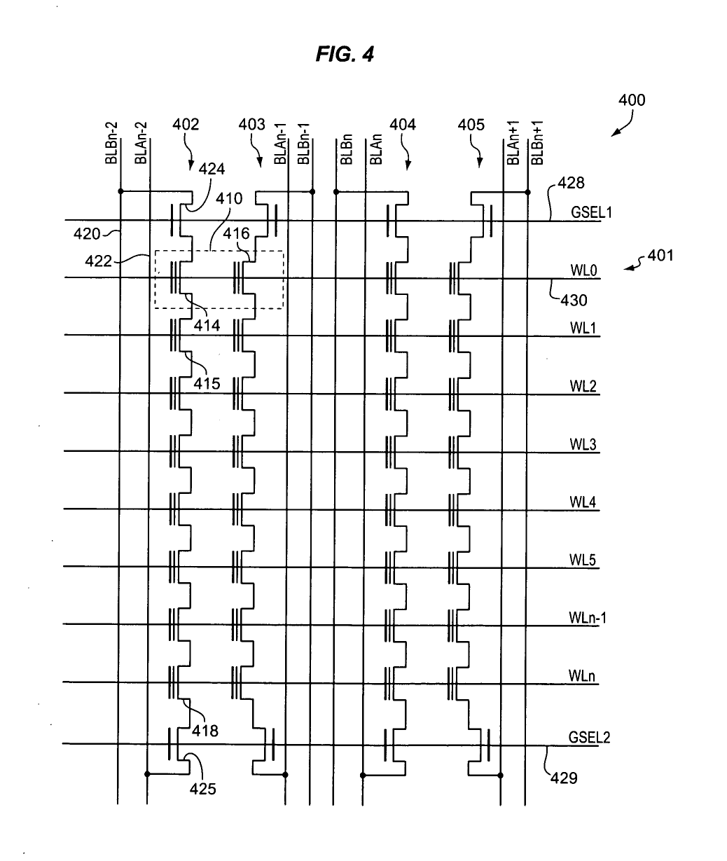

FIG. 4 illustrates an application of the TLCP strategy in a portion of a 3-bit per cell TLC NAND flash memory core 400. Memory core 400 includes rows, such as 401, and columns, such as 402, of TLC pairs, such as 410. Each TLC pair includes a first floating gate transistor 414 and a second floating gate transistor 414. The first transistors 414, 415, etc., in a column, such as 402, are connected in series source to drain. Herein, no distinction is made between sources and drains, since, as known in the art, transistors can generally be implemented in voltages in either direction. Thus, sources and drains are all referred to as source/drains. Two pass-gate transistors 424 and 425 and an “A” bit line 420 and a “B” bit line 422 are associated with each column, such as 402. One source/drain of transistor 424 is connected to the “B” bit line 420 and the other source/drain is connected to the first 414 of the floating gate transistors in the corresponding column 402, while the gate is connected to a gate select line 428 carrying the GSESL1 signal. One source/drain of transistor 425 is connected to the “A” bit line 422 and the other source/drain is connected to the last 418 of the floating gate transistors in the corresponding column 402, while the gate is connected to a gate select line 429 carrying the GSESL2 signal. The second floating gate transistor, such as 416, in each TLC pair is also in series with other floating gate transistors in its column 403 which are connected to their corresponding pass-gate transistors and “A” and “B” bit lines. Likewise, other columns of cell pairs, such as columns 404, 405, etc., are part of array 400, with the gates of all floating gate transistors in each row, such as 401, connected to the corresponding word line, such as 430. Altogether there are n rows of cells, with n preferably 7, 15, or 31 depending on the NAND cell implementation as known in the flash memory art. However, unlike prior art NAND flash memories, each floating gate transistor 414, 416, etc., will be written with three logic states, i.e., Low threshold, Medium threshold, High threshold. As discussed above, each NAND flash cell pair 410 can exist in 3×3 or nine logic states to represent two data bits. Since each of the bit lines will only have three different levels because of the three different states of the selected floating gate transistor, i.e., high resistance (off), medium resistance (partial on), low resistance (on), the complexity of the reading and sensing circuitries can be greatly reduced, the details of which have already been discussed. Other elements of the NAND flash memory 400 are known in the flash art, and thus will not be discussed herein.

The invention contemplates that split-gate flash memory cells or dual floating gate flash cells can be incorporated into the NAND memory just discussed, or other flash memories discussed herein in either NAND or NOR architectures. These split-gate flash memory cells and dual floating gate flash cells and the various address architectures which are used in such flash memories are well-known in the art and thus will not be discussed in detail herein. Any other known or future flash architecture can be used. For example, for circuit design or layout considerations, BLAn, n+1, n−1, n−2 bit lines, which are in the vertical direction in FIG. 4, can be combined for each cell pair, or neighboring cells, or groups of cells vertically. The vertical BLAn, n+1, n−1, n−2 lines can also be combined to run in horizontal direction in the figure. The BLA lines can also be connected to GROUND directly with all the pass-gates driven by GSEL2 removed.

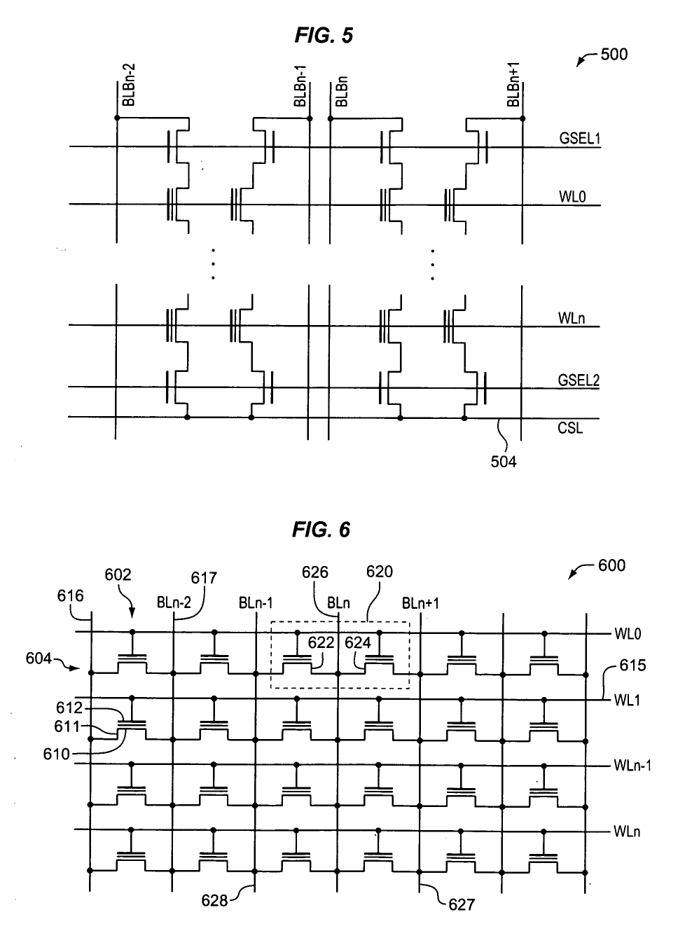

FIG. 5 shows another architectural variation. The memory core 500 is the same as that of FIG. 4, except the four “A” bit lines have been replaced with a single horizontal line 504 which carries a CSL signal. This “CSL” line 504 can also be shared with a mirrored block of cells as known in the art. Any of the memory cores described above or below can also be varied for layout efficiency as known in the art. For example, two TLC NAND flash cells can be folded so that there are four transistors in one cell instead of two. The same is applicable to the TLC dual floating gate NAND flash and the TLC split-gate floating gate NAND flash memories. Any other prior art folded architecture can be used in combination with the TLCP strategy.

An example of an NOR flash memory core array 600 is shown in FIG. 6. Array 600 comprises columns, such as 602, and rows, such as 604, or floating gate flash cells, such as 610. The source/drains, such as 611, of the transistors, such as 610, in a row are connected to the vertical bit lines, such as 616, and the gates, such as 612, are connected to the word lines, such as 615. A TLC pair, such as 620 comprises a first TLC cell 622 and a second TLC cell 624. The bit line 626 at the center of the cell is used as virtual ground, and the bit lines on the left 628 and right 627 are shared with the neighboring cells. The sharing of the bit lines causes higher power dissipation during writing operations, though this is not a significant disadvantage if the cell is written to infrequently. The memory core 600 is accessed a cell pair at a time obtaining three data bits of information.

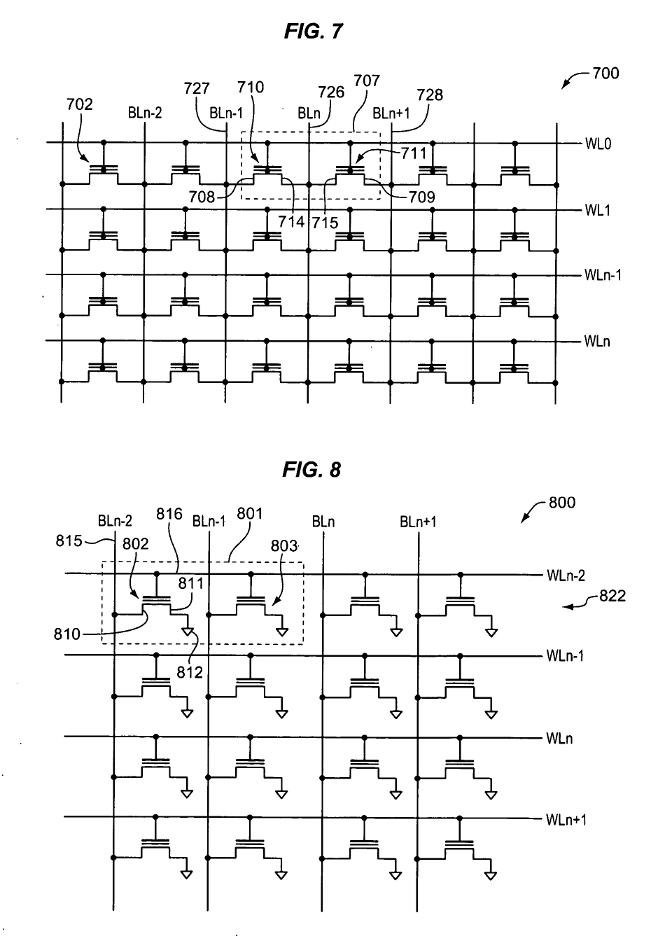

FIG. 7 shows an alternative architecture of an NOR array, i.e., a dual floating gate virtual ground NOR flash memory core array 700. Array 700 has the same structure as array 600, except that the floating gate transistors 610, array 600 are replaced by dual floating gate transistors, such as 702, 710, and 711. In this architecture, there are four transistors, 708, 709, 714, and 715 in a cell 707. Because of the TLC dual floating gates in each transistor, each of the vertical bit lines can be used as either a data bit line or virtual ground line depending on which side of the dual floating gate is being accessed. Preferably, the read and write operations are still performed on one transistor pair at a time to obtain three bits of data. For example, cell 707 comprises first dual floating gate transistor 710 and second dual floating gate transistor 711. This cell 707 is capable of holding six bits of data, but only two of the four transistors, for example, first transistor 714 and second transistor 715, are accessed at a time to obtain three bits of data. When transistors 714 and. 715 are accessed, line 726 acts as the bit line and lines 727 and 728 are virtual grounds. Other address architectures can be used with the NOR memories just discussed. For example, the bit line between each pair of cells in FIG. 6 can be connected as a designated virtual ground, and an additional bit line can be added parallel to each of the other bit lines, with a single transistor in each row connected to each of the bit lines. That is, the bit lines are not shared with neighboring cells. With this architecture, the core array area is larger, but the power dissipation is much smaller. In another architecture, every bit line of FIG. 6 is replaced with two bit lines, with one bit line connected to the adjacent row of transistors. Thus, none of the vertical lines are shared between adjacent transistors. The vertical lines can be data lines of virtual grounds. Again, any of these architectures can be folded and many possible select circuitries are available. As another possible architecture, every other transistor in FIG. 6 can be arranged vertically, so that a TLC pair includes a horizontal transistor and a vertical transistor. This permits the bit lines to be placed closer together, with a corresponding increase in density, though it is more difficult to match the properties of the paired transistors. Similarly, the architecture with every other transistor arranged vertically can be used with the dual floating gate transistors 702 of FIG. 7. Again, in this architecture, each cell stores six bits of data, though only two of the four transistors in a cell are addressed at a time to read or write three bits of data. As for the architecture of FIG. 7, each vertical line can be either a bit line or virtual ground depending on which transistors are being accessed.

FIG. 8 shows another array architecture for a TLC NOR flash memory. In array 800, each TLC pair 801 includes a first floating gate transistor 802 and a second floating gate transistor 803. One source/drain 810 of each transistor, such as 802, is connected to its corresponding bit line 815, and the other source/drain 811 is connected to ground 812. The gates of the transistors in a row 822 are connected to the word line 816 associated with the row.

Similarly, any other known flash architecture can be implemented to obtain three bits from two cells.

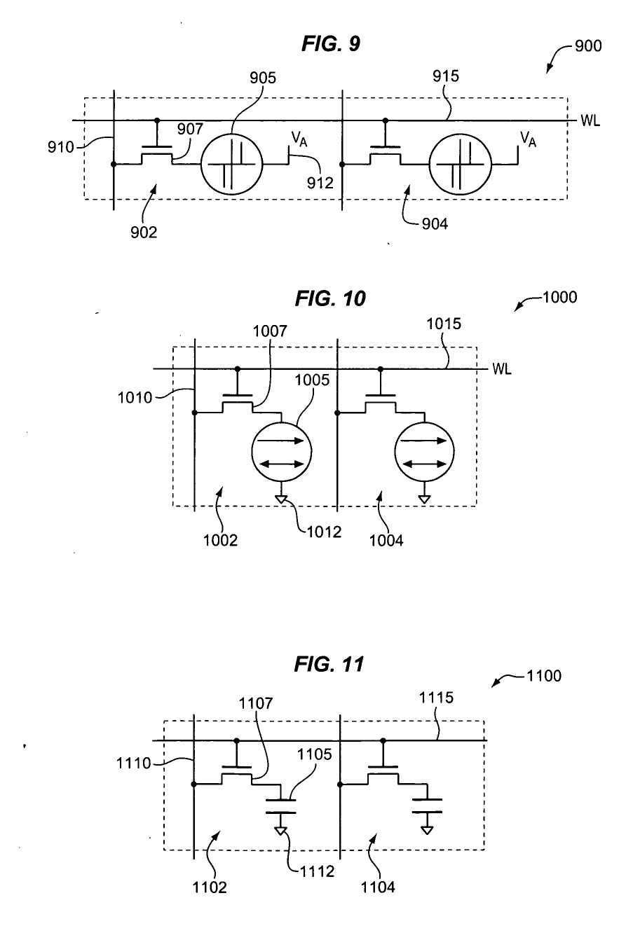

FIG. 9 shows a TLC memory cell pair 900 for a TLC Ovonic Unified Memory (OUM). Cell pair 900 includes a first OUM cell 902 and a second OUM cell 903. Each cell, such as 902, includes a transistor 907, preferably an MOS transistor, and an OUM element 905. One source/drain of transistor 907 is connected to the corresponding bit line 910 and the other source/drain is connected to the OUM element 905. The gate of transistor 907 is connected to its corresponding word line 915. The other side of OUM element 905 is connected to a source 912 of a reference voltage VA. In the OUM, the digital data of 1s and 0s are stored as amorphous (high resistance and non-reflective) or crystalline (low resistance and reflective) structures. By using electrical energy controlled by transistors, such as 907, the desired digital data can be written into the OUM cells. In conventional applications, only 0s or 1s, representing only two states, are written into the OUM cells. The read operation is done by sensing either the low or the high resistive states of the OUM cells. However, the resistance of the OUM element 905 can vary depending on the magnitude of the write current applied to the cell during the write operation. Thus, by using multi-level write currents, multiple levels of resistance can be written into a single cell to represent multiple bits of digital data. In this manner, the TLCP strategy can be implemented in OUM. Similarly, any other known OUM architecture can be implemented to obtain three bits from two cells.

FIG. 10 shows a TLC memory cell pair 1000 for a TLC Magnetresistive RAM (MRAM). Cell pair 1000 includes a first MRAM cell 1002 and a second MRAM cell 1003. Each cell, such as 1002, includes a transistor 1007, preferably an MOS transistor, and an MRAM element 1005. One source/drain of transistor 1007 is connected to the corresponding bit line 1010 and the other source/drain is connected to the MRAM element 1005. The gate of the transistor 1007 is connected to its corresponding word line 1015. The other side of MRAM element 1005 is connected to a ground voltage 1012. In the MRAM, the digital data of 1s and 0s are stored as magnetic states that have different resistances. By using electrical energy controlled by transistors, such as 1007, the desired digital data can be written into the MRAM cells. In conventional applications, only 0s or 1s, representing only two states, are written into the MRAM cells. The read operation is done by sensing either the low or the high resistive states of the MRAM cells. However, the resistance of the MRAM element 1005 can vary depending on the magnitude of the write current applied to the cell during the write operation. Thus, by using multi-level write currents, multiple levels of resistance can be written into a single cell to represent multiple bits of digital data. In this manner, the TLCP strategy can be implemented in MRAM. Similarly any other known MRAM architecture can be implemented to obtain three bits from two cells.

In dynamic storage components like DRAM, 1TSRAM, PSRAM, Dynamic Register array, Dynamic FIFO, etc., a capacitor is being used in the memory cell to store the desired logic state. As an example of a dynamic memory to which the TLCP strategy is applied, FIG. 11 shows a TLC memory cell pair 1100 for a TLC Dynamic RAM (DRAM). This cell can be used in many dynamic storage applications, such as 1TSRAM, PSRAM, etc. Cell pair 1100 includes a first DRAM cell 1102 and a second DRAM cell 1103. Each cell, such as 1102, includes a transistor 1107, preferably an MOS transistor, and a capacitor 1105. One source/drain of transistor 1107 is connected to the corresponding bit line 1110 and the other source/drain is connected to the capacitor 1105. The gate of the transistor 1107 is connected to its corresponding word line 1115. The other side of capacitor 1105 is connected to a ground voltage 1112. The storage capacitor is charged or discharged by a voltage placed across it to represent the digital data of 1s and 0s. An intermediate charge level can also be written into the capacitor, thus giving three states in the storage cell. Two of the storage cells with tri-level storage scheme can be put together to represent three data bits. The three levels of charge stored in the capacitor can be High, Medium, and Low. Depending on the circuit design considerations, the appropriate levels will be implemented differently, i.e., Low can be very little charge, no charge, or even negative charge. Medium may not mean in the middle. It can be 80% to 10% or below depending on the design considerations. In this manner, the TLCP strategy can be implemented in DRAM.

FIG. 12 shows another example of a dynamic storage cell pair, i.e., a dynamic register cell pair 1200, which includes a first dynamic register 1202 and a second dynamic register 1203. Each dynamic register, such as 1202, includes a gate transistor 1207, a storage capacitor 1205, a read transistor 1220, and a read select transistor 1222. Transistors 1207, 1220, and 1222 are preferably MOS transistors and most preferably CMOS transistors. One source/drain of transistor 1207 is connected to write bit line 1210 and the other source/drain is connected to the side of capacitor 1205 connected to node 1213. The gate of transistor 1207 is connected to the write word line 1216 carrying the signal WLW. The other side of capacitor 1205 is connected to ground 1212. Node 1213 is also connected to the gate of transistor 1220. One source/drain of transistor 1220 is connected to ground, and the other is connected to one source/drain of transistor 1222. The other source/drain of transistor 1222 is connected to the read bit line 1211. The gate of read select transistor 1222 is connected to read word line 1215 carrying signal WLR. As known in the art, dynamic register 1202 operates as follows. When write word line 1216 is high, transistor 1207 is on and the voltage on write bit line 1210 determines a charge placed on capacitor 1205. The charge on capacitor 1205 determines the voltage on gate of transistor 1220, which determines the current or resistance of transistor 1220. When read word line 1215 is high, a voltage or current can be read on bit line 1211 to read the state of capacitor 1205. As in the DRAM, three charge states can be stored on capacitor 1205, which will determine three resistive states of transistor 1220. Again, depending on the circuit design considerations, the appropriate levels will be implemented differently, i.e., Low can be very little charge, no charge, or even negative charge. Medium may not mean in the middle. It can be 80% to 10% or below depending on the design considerations, such as the threshold of transistor 1220. In this manner, the TLCP strategy can be implemented in DRAM. Again, the architecture and layout of the various parts of the DRAM and dynamic register discussed above can be varied widely. Similarly, any other known dynamic architecture can be implemented to obtain three bits from two cells.

The capacitors used in any TLCP cell with dynamic charge storage can be any capacitor available in the specific process, e.g., MIM, PIP, PN junction, trench capacitor, stacked capacitor, sidewall capacitor, NMOS capacitor, PMOS capacitor, native NMOS capacitor, native PMOS capacitor, depletion NMOS capacitor, etc. To maximize the capacitance on an MOS capacitor, the MOS transistor can be depletion implanted with Negative VT, or a native NMOS with VT close to 0V, or NMOS transistor with the gate node connected to a high voltage so the NMOS transistor will be in an ON state to maximize the effective capacitance. FIG. 17 shows an example of a TLCP DRAM cell pair 1700 with NMOS capacitors, such as 1705. Cell pair 1700 includes a first cell 1702 and a second cell 1703. Each cell includes an MOS access transistor 1707 and an MOS capacitor 1705. The access transistor 1707 has one source/drain connected to bit line 1710 and the other connected to one side of capacitor 1705 and its gate connected to word line 1716. As known in the dynamic RAM art, the NMOS capacitor 1705 includes a gate 1712 that is connected to a line 1717 carrying a high voltage VH. The NMOS capacitors are turned ON by VH. The NMOS capacitors can be depletion NMOS, native NMOS, or NMOS transistors.

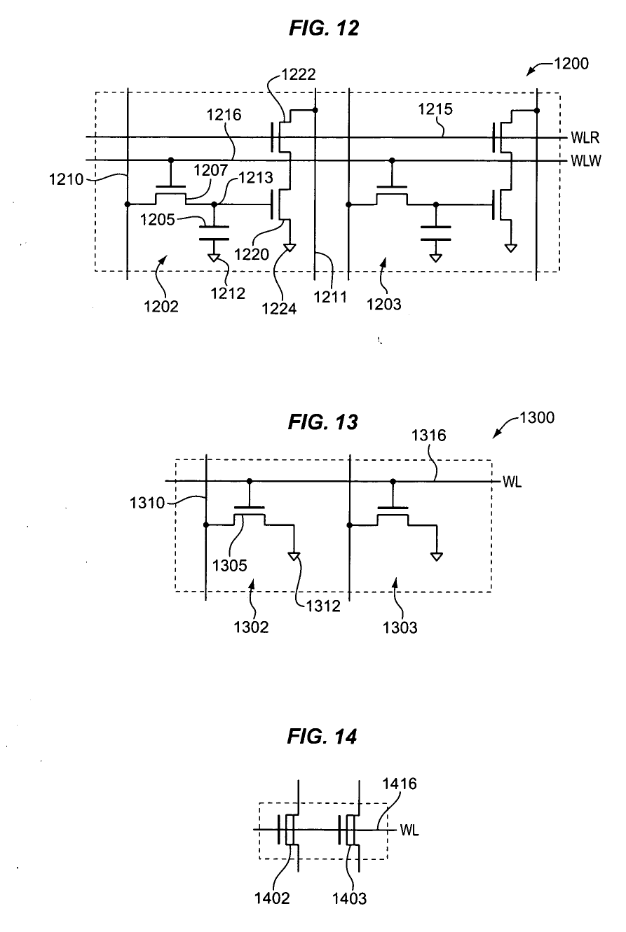

The TLCP strategy can also be used in Read Only Memories (ROMs). There are many types of ROM memories. The NOR style ROM has cells with select transistors of different strengths or different widths to implement multi-level, e.g., 2-bit-per-cell ROM. The NAND style ROM uses implants for programming. It is possible to adjust the levels of the implants for each cell to implement multi-level. For Virtual Ground style ROM, the selected ROM cell transistor can be like the NOR style with various channel widths to implement multiple bits of data per cell. FIG. 13 shows a TLC NOR ROM cell pair 1300, including a first ROM cell 1302 and a second ROM cell 1303. As is known in the art, one source/drain of capacitor 1305 is connected to bit line 1310, and the other is connected to ground 1312. The gate of transistor 1305 is connected to the corresponding word line 1316. Three different implants or channel widths can be used for transistor 1302 to yield three states to implement the storage and reading of three bits from pair 1300.

FIG. 14 illustrates a TLC NAND ROM cell pair, which includes first transistor 1402 and second transistor 1403 with their gates connected to word line 1416. As known in the art, each column of transistors is connected in series, with a pull-up device at one end of the series and a ground at the other. All word lines are high except for the row selected. Again, if each transistor 1402 and 1403 has one of three states, three bits can be read from the cell pair 1400. Similarly, any other known ROM architecture can be implemented to obtain three bits from two cells.

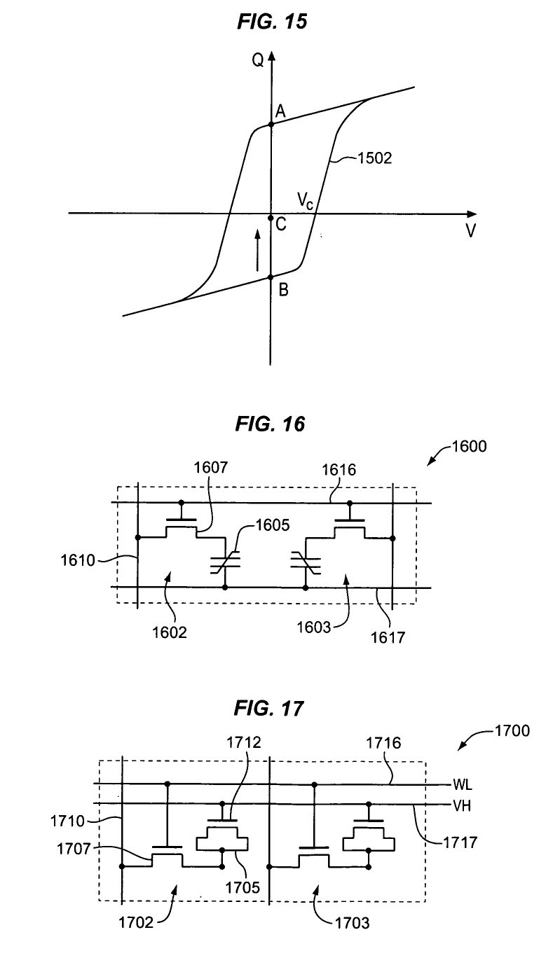

The TLCP strategy can also be used with ferroelectric memories. FIG. 15 shows a hysteresis curve 1502 of a ferroelectric cell, which is generally a capacitor. As known in the art, hysteresis curve 1502 is a graph of polarization charge Q versus voltage V. A conventional ferroelectric memory utilizes the two states A and B to provide a two-state memory cell. However, the B state can be shifted in the direction of the arrow to C when a ferroelectric capacitor is disturbed but not switched to the A state in the write operation. In this manner, three different states can be achieved in a ferroelectric capacitor, which can be distinguished by placing a voltage across the capacitor and sensing its response. FIG. 16 shows an exemplary TLC ferroelectric memory cell pair 1600, which includes a first ferroelectric cell 1602 and a second ferroelectric cell 1603. Each cell, such as 1602, includes a transistor 1607, which preferably is an MOS transistor, and most preferably a CMOS transistor, and a capacitor 1605. One source/drain of transistor 1607 is connected to bit line 1610, and the other is connected to one side of capacitor 1605. The other side of capacitor 1605 is connected to plate line 1617. When a word line 1616 is high and a voltage sufficiently higher than the voltage on plate line 1617 is placed on bit line 1610, the ferroelectric capacitor 1605 switches to one state, say state A. When a voltage sufficiently lower than the voltage on plate line 1617 is placed on bit line 1619 when word line 1616 is high, capacitor 1605 switches to state B. Here, “sufficiently higher” or “sufficiently lower” means a voltage difference equal to or greater than the ferroelectric coercive voltage, which in most ferroelectric memories is 2.5 volts to 5 volts. However, if the voltage difference is significant, say one to two volts, but not equal to the coercive voltage, the capacitor can be placed in state C. As indicated above, these three states can be used to write and read three bits to cell pair 1600.

There are probably hundreds of different architectures of ferroelectric memories, all of which can be combined with the TLCP strategy to obtain three bits from a pair of cells. Some of these are the 1T/1C cell described in U.S. Pat. No. 4,893,272, the trinion cell described in U.S. Patent Publication No. 20030206430, and the chain cell described in U.S. Pat. No. 6,483,373, all of which are hereby incorporated by reference to the same extent as though fully disclosed herein.

Since the preferred TLCP strategy uses memory cells with three levels, it is a lot easier to implement as compared to a regular 2-bit-per-cell memory cell with four levels or MLC cells with multiple levels greater than or equal to 4. As indicated by the examples above, the TLCP strategy can be used with nearly every memory cell architecture. This strategy is suitable for both volatile and non-volatile memories. It is also applicable to mirror-bit two transistor styles of memory cell with each side being tri-level. The two TLC cells can be located together in one unit cell, or in different column or row locations, or even in other memory blocks depending on the circuit implementations. The specific implementation of the TLC pair is dependent on each individual memory cell technology. That is, the invention is not limited to the exact implementations of each individual technology described herein, but is broad enough to include using the preferred pair of tri-level cells, preferably having exactly only one extra level from a regular single bit memory cell, to get one more bit of data out of the two cells.

With any embodiment, the TLCP strategy gives a 50% increase in memory storage capacity with a much less challenging circuit development effort and roughly the same silicon area. Many of the non-volatile technologies like EEPROM, EPROM, FeRAM, OUM memory, and various types of flash memories, which includes stacked-gate cells, two-transistor cells, split-gate cells, etc., can be easily modified to have the 50% increase in storage capacity. All DRAMs including synchronous or asynchronous DRAMs, DDR DRAMs, QDR DRAMs, PSRAMs, 1TSRAMs, etc., can also be converted to this TLCP strategy to gain a 50% increase in storage capacity. In all of the above figures described, where NMOS passgates are shown in the schematics as examples, they could be PMOS, N/P MOS, bipolar transistors, finFet, triple-gate Transistors, etc., depending on circuit design requirements.

There has been described novel electronic memory architectures utilizing a tri-level memory cell. Now that the tri-level cell and various memory architectures using the cell have been described, those skilled in the electronics arts may make many variations. It should be understood that the particular embodiments shown in the drawings and described within this specification are for purposes of example and should not be construed to limit the invention, which will be described in the claims below. Further, it is evident that those skilled in the art may now make numerous uses and modifications of the specific embodiments described, without departing from the inventive concepts. It is also evident that the methods recited may, in many instances, be performed in a different order, or equivalent components may be used in the memories, and/or equivalent processes may be substituted for the various processes described. Consequently, the invention is to be construed as embracing each and every novel feature and novel combination of features present in and/or possessed by the invention herein described.

1. An electronic memory comprising:
a memory cell pair comprising a first memory cell and a second memory cell, each said memory cell comprising a single electronic storage element capable of existing in three or more electronic memory states;
a write circuit for writing three or more data bits to said memory cell pair, wherein at least one of said data bits is used to determine an electronic memory state of said first cell and an electronic memory state of said second cell; and
a read circuit for reading three or more data bits from said memory cell pair, wherein at least one data bit is determined by an electronic memory state of said first cell and an electronic memory state of said second cell.

2. An electronic memory as in claim 1 wherein said memory cell comprises either a single bit line cell or a two bit lines cell, and two of such cells together form said memory cell pair.

3. An electronic memory as in claim 1 wherein said memory cell pair includes an extra state that is not used in representing said three or more data bits.

4. An electronic memory as in claim 1 wherein said first and second memory cells are capable of existing in an odd number of states.

5. An electronic memory as in claim 4 wherein said first and second memory cells are capable of existing in three electronic memory states for a total of nine possible memory state combinations and there are three of said data bits.

6. An electronic memory as in claim 5 wherein one of said nine possible memory state combinations is not used in directly recording said three data bits.

7. An electronic memory as in claim 5 and further including a tri-level sense amplifier for sensing three electronic levels and for outputting two logic signals.

8. An electronic memory as in claim 7 and further including two of said tri-level sense amplifiers and a decoder for decoding the four logic signals output by said sense amplifiers into three data bits.

9. An electronic memory as in claim 8 and further including an Error Detection and Correction (EDAC) circuit between at least one of said Tri-level sense amplifiers and said decoder, thereby taking advantage of the real life physical fault situation to minimize complexity of the EDAC circuits.

10. An electronic memory as in claim 5 wherein said memory is a flash memory.

11. An electronic memory as in claim 5 wherein said memory is a read only memory (ROM).

12. An electronic memory as in claim 5 wherein said memory is a dynamic memory.

13. An electronic memory as in claim 12 wherein said memory is a dynamic random access memory (DRAM) or a dynamic register.

14. An electronic memory as in claim 12 wherein said memory cells include an MOS capacitor.

15. An electronic memory as in claim 5 wherein said memory is an ovonic unified memory (OUM).

16. An electronic memory as in claim 5 wherein said memory is a magnetoresistive random access memory (MRAM).

17. An electronic memory as in claim 5 wherein said memory is a ferroelectric memory.

18. An electronic memory as in claim 17 wherein said memory is a non-volatile memory.

19. An electronic memory as in claim 17 wherein said memory is a destructive read out memory.

20. An electronic memory as in claim 17 wherein said memory is a non-destructive readout memory.

21. An electronic memory as in claim 5 wherein said memory is an NAND memory.

22. An electronic memory as in claim 5 wherein said memory is an NOR memory.

23. A method of reading an electronic memory, said method comprising:
reading three electronic levels from each of 2N memory cells, where N is an integer; and
decoding said electronic levels into 2N+N data bits.

24. A method as in claim 23 where said reading comprising reading three electronic levels from each of two memory cells and said decoding comprises decoding said electronic levels into three data bits.

25. A method of writing to an electronic memory, said method comprising:
receiving 2N+N bits of data, where N is an integer; and
writing said bits of data into three electronic levels in each of 2N memory cells.

26. A method as in claim 25 wherein said receiving comprises receiving three data bits and said writing comprises writing three electronic levels into each of two memory cells.
